(19) United States
(12) Patent Application Publication
(10) Pub. No.: US 2005/0224910 A1
(43) Pub. Date: Oct. 13, 2005

(54) Semiconductor integrated circuit having polysilicon fuse, method of forming the same, and method of adjusting circuit parameter thereof

(75) Inventors: Isamu Kuno, Mihama-ku (JP); Hideaki Tokita, Utsunomiya (JP)

Correspondence Address: OLIFF & BERRIDGE, PLC, P.O. BOX 19928, ALEXANDRIA, VA, 22320, US

(73) Assignee: KAWASAKI MICROELECTRONICS INC., Mihama-ku (JP)

(21) Appl. No.: 11/090,199

(22) Filed: Mar. 28, 2005

(30) Foreign Application Priority Data
Apr. 12, 2004 (JP) 2004-116880

(51) Int. Cl. H01L 29/00

(52) U.S. Cl. 257/529

(57) ABSTRACT

Exemplary semiconductor integrated circuits are disclosed that include polysilicon fuses that can be programmed by supplying programming currents. The fuse is formed of a polysilicon film having a sheet resistance of 1.7 to 6 kΩ/sq. As a result, the polysilicon fuse has a high resistance and can be programmed with low current. Accordingly, the fuse can be programmed with a high yield even when the programming current is supplied through a wire having a high resistance.

### CROSS-REFERENCE TO RELATED APPLICATION

The disclosure of Japanese Patent Application No. 2004-116880, filed on Apr. 12, 2004 including the specification, drawings and Abstract is incorporated herein by reference in its entirety.

### BACKGROUND

This invention relates to semiconductor integrated circuits having polysilicon fuses that can be programmed by supplying programming currents, and methods of forming the same. This invention also relates to methods of adjusting circuit parameters of semiconductor integrated circuits.

In order to adjust resistance or other parameters in a semiconductor integrated circuit, devices such as zener-zap type anti-fuses or polysilicon fuses are used. The polysilicon fuse is formed using a resistor pattern, which is formed of a polysilicon film. The fuse is destroyed, or programmed, with a heat generated by supplying an excessive current (or a programming current) to the resistor pattern through electrodes provided at both ends of the resistor pattern.

Conventionally, a high voltage and a high current are required to destroy the fuse. Accordingly, various techniques were proposed to decrease one or both of the voltage and the current required to destroy and to program the polysilicon fuse.

Patent Document 1 (Japanese Laid-open Patent 55-180003) discloses a polysilicon fuse memory. Oxidizing the surface of the fuse decreases the thickness and the width of the polysilicon fuse, which is formed of the same polysilicon film used for forming a gate electrode.

Patent Document 2 (Japanese Laid-open Patent 59-68946) discloses a polysilicon fuse pattern that crosses over a trapezoid region. The polysilicon fuse has a high-resistance portion over the trapezoid region, where the fuse pattern is made thinner and has a higher resistance than the other portions.

Patent Document 3 (Japanese Laid-open Patent 63-246844) discloses a fuse using a second layer polysilicon pattern that crosses over a first layer polysilicon pattern via an interlayer dielectric film. The current is concentrated at the thin portion in the second layer polysilicon pattern formed at the stepped region crossing over the first layer polysilicon pattern.

Patent Document 4 (Japanese Laid-open Patent 4-97545) discloses a fuse with a polysilicon pattern having a bent region. A depressed region is formed under the internal portion of the bent region on a surface of the field dielectric film under the fuse. Thereby, the current is concentrated at the bent region where the thickness of the polysilicon film is decreased over the step at the depressed region.

Patent Document 5 (Japanese Laid-open Patent 4-373147) discloses a high-resistance region doped with boron at the center of a fuse body, which is formed of a polysilicon film doped with phosphorus. Thereby, the heat generation is concentrated at the high-resistance region without making the overall resistance of the fuse too high.

Patent Document 6 (U.S. Pat. No. 5,420,456) discloses a bent region in a fuse link formed of polysilicon. Thereby, the electric current is concentrated at the bent region.

Patent Document 7 (Japanese Laid-open Patent 2000-40790) discloses a polysilicon fuse having a region of a small cross-section area and regions with a large cross-section area on both sides of the region of the small cross-section area. It arranges electrodes in the regions of the large cross-section areas apart from the region of the small cross-section area with a certain length.

Patent Document 8 (U.S. Pat. No. 5,969,404) discloses a programmable resistor formed of a stack of a polysilicon layer and a silicide layer on the polysilicon layer. Before applying a programming current, the programmable resistor has a low resistance determined by the resistance of the silicide layer. By applying the programming current, a disconnected region is formed in the silicide layer and the programmable resistor becomes to have a high resistance determined by the ratio of the resistances of the polysilicon layer and that of the silicide layer. As an example of the resistance of the polysilicon layer, Patent Document 8 discloses a value of 1000 Ω/sq (ohms per square).

Most of the conventional art described above decreases the voltage and/or current necessary to destroy the fuses by modifying the shape of the fuses to concentrate the current at specific regions. The conventional polysilicon fuses described above generally are formed of polysilicon films with relatively low resistances. For example, the highest resistance of the polysilicon film disclosed in Patent Documents 1 through 7 is 100 Ω/sq. (See Patent Document 7).

Patent Document 8 discloses a sheet resistance of a polysilicon layer of 1000 Ω/sq. However, the fuse disclosed in Patent Document 8 has a layered structure including a polysilicon layer and a silicide layer on the polysilicon layer. Further, in the fuse disclosed in Patent Document 8, applying a programming current only disconnects the silicide layer without disconnecting the polysilicon layer.

That is, the programmable resistor disclosed in Patent Document 8 is not a polysilicon fuse, which is formed of a polysilicon film without stacking with a silicide film. The polysilicon fuse is different than the programmable resistor disclosed in Patent Document 8. For example, in a polysilicon fuse: (1) the resistance of the fuse before its destruction is determined by the resistance of the polysilicon layer; and (2) applying an excessive current destroys or disconnects the polysilicon layer.

Accordingly, the resistance value of the polysilicon layer disclosed in Patent Document 8 cannot be used as a reference to determine the resistance of the polysilicon film for forming a polysilicon fuse.

Further, Patent Document 5 discloses a high resistance region at the center of the fuse body. However, Patent Document 5 dopes phosphorus in the whole area of the fuse with a concentration of 10²⁰ to 10²¹ cm⁻³ and forms the high resistance region only at the center of the fuse body. Accordingly, the sheet resistance of the polysilicon film other than the high resistance region is considered to be lower than the value disclosed in Patent Document 7.

In other words, Patent Document 5 forms a fuse using a low resistance polysilicon film and forms a high resistance region only at the center of the fuse body.

As described above, fuses are generally formed of polysilicon films with relatively low resistance. Accordingly, the resistance of the fuse is low. Because the resistance of the polysilicon fuse is low, a high current is required to generate enough heat to destroy the fuse, unless the shape of the fuse is modified.

If a high current is required, a large area is required to arrange a circuit to supply the current. On the other hand, a modification of the shape of fuse requires a large area to arrange the fuse. In either case, the area of the semiconductor integrated circuit including the fuse becomes large.

Moreover, when the programming current is supplied from outside of the semiconductor integrated circuit, the current also flows through a wire on a substrate on which the semiconductor integrated circuit is mounted. Accordingly, when the resistance of the wire on the substrate is high, it is difficult to supply a sufficient programming current from outside of the semiconductor integrated circuit.

For example, a semiconductor integrated circuit for driving an LCD (liquid crystal display) panel may be mounted on a glass substrate, which is common to the LCD panel. A wire on a glass substrate is generally formed of a transparent electrode film, which has a high resistance. Accordingly, it is difficult to supply a sufficient current to destroy the fuse in a semiconductor integrated circuit mounted on a glass substrate.

### SUMMARY

An exemplary object of this invention is to solve the above-mentioned problems and to provide a semiconductor integrated circuit including a polysilicon fuse that can be programmed with a low current. Another exemplary object of this invention is to provide a method of forming a semiconductor integrated circuit including a polysilicon fuse that can be programmed with a low current. A further exemplary object of this invention is to provide a method of adjusting a circuit parameter of a semiconductor integrated circuit by supplying a programming current through a wire having a high resistance.

In order to solve above-mentioned problems, various exemplary embodiments according to this invention provide a semiconductor integrated circuit including a fuse. The fuse is programmable by supplying a programming current and includes a polysilicon pattern formed of a polysilicon film. The polysilicon pattern includes electrode regions and a resistor region between the electrode regions, and at least a portion of the resistor region except for end portions adjacent to the electrode regions has a sheet resistance of 1.7 to 6 kΩ/sq.

According to various exemplary embodiments, a resistance of the fuse may be not lower than about 3 kΩ.

According to various exemplary embodiments, each of the end portions of the resistor region may have a first width and is connected directly (or through a tapered region) to the electrode region having a second width larger than the first width.

According to various exemplary embodiments, the semiconductor integrated circuit may further include a resistor element formed of the polysilicon film having the sheet resistance of 1.7 to 6 kΩ/sq.

In order to solve above-mentioned problems, various exemplary embodiments according to this invention provide a semiconductor integrated circuit mounted on a substrate having a transparent electrode film. The semiconductor integrated circuit includes a fuse including a polysilicon pattern formed of a polysilicon film. The polysilicon pattern includes electrode regions and a resistor region between the electrode regions, the fuse is programmable by supplying a programming current from outside of the semiconductor integrated circuit through an external wire formed of the transparent electrode film, and at least a portion of the resistor region except for end portions adjacent to the electrode regions has a sheet resistance of 1.7 to 6 kΩ/sq.

According to various exemplary embodiments, the transparent film may be one of an indium-tin oxide, an indium-zinc oxide, and an indium-tin-zinc oxide film.

In order to solve above-mentioned problems, various exemplary embodiments according to this invention provide a method of forming a semiconductor integrated circuit comprising a polysilicon fuse including a polysilicon pattern. The method includes forming a polysilicon pattern over a surface of a semiconductor substrate, patterning the polysilicon film to form the polysilicon pattern to include electrode regions and a resistor region between the electrode regions, doping, before or after the patterning, the resistor region to have a sheet resistance of 1.7 to 6 kΩ/sq., and doping, before or after the patterning, the electrode regions more heavily than the resistor region without doping the resistor region.

In order to solve above-mentioned problems, various exemplary embodiments according to this invention provide a method of adjusting a circuit parameter of a semiconductor integrated circuit. The method includes integrating a fuse that includes a polysilicon pattern formed of a polysilicon film in the semiconductor integrated circuit, mounting the semiconductor integrated circuit on a substrate having an external wire formed of a transparent electrode film, and programming the fuse by supplying a programming current to the fuse through the external wire. The polysilicon pattern includes electrode regions and a resistor region between the electrode regions, and at least a portion of the resistor region except for end portions adjacent to the electrode regions has a sheet resistance of 1.7 to 6 kΩ/sq.

### BRIEF DESCRIPTION OF THE DRAWINGS

Various exemplary embodiments will be described in detail, with reference to the following figures, wherein:

FIG. 1 is an exemplary drawing that shows a polysilicon fuse integrated in a semiconductor integrated circuit;

FIG. 2 is an exemplary diagram of one-bit memory circuits utilizing the exemplary polysilicon fuse shown in FIG. 1;

FIG. 3 is an exemplary drawing that shows a liquid crystal display device including a driver IC that includes the polysilicon fuse shown in FIG. 1; and

FIG. 4 is an exemplary graph that shows voltages, currents, and powers required for programming the polysilicon fuse shown in FIG. 1 (in relation to the sheet resistance of the polysilicon film used for forming the fuse).

### DETAILED DESCRIPTION OF EMBODIMENTS

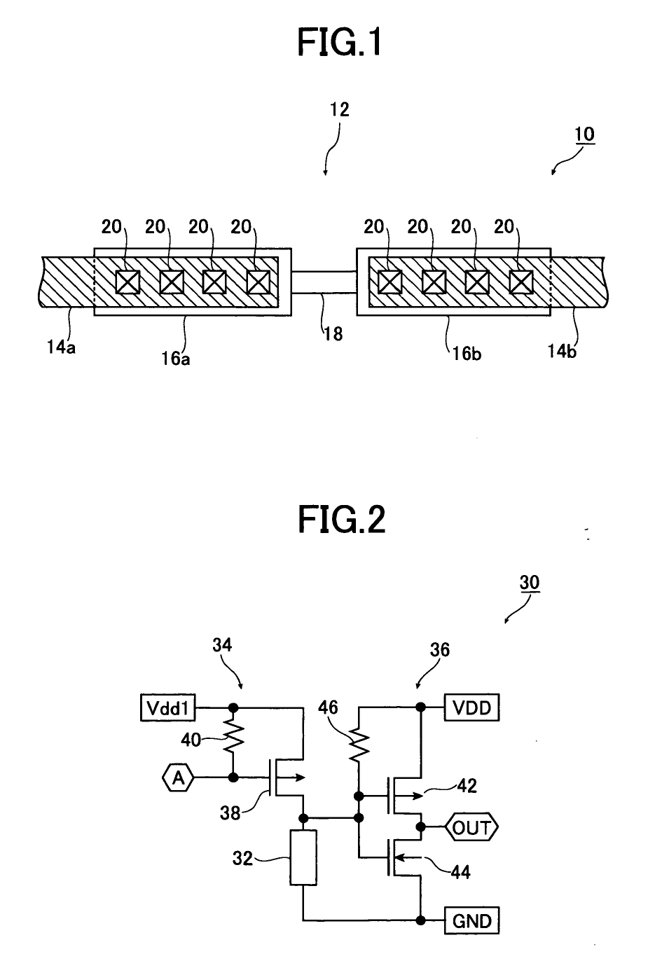

FIG. 1 is an exemplary drawing that shows a portion of a semiconductor integrated circuit. According to various exemplary embodiments, a semiconductor integrated circuit includes a polysilicon fuse 10 that can be destroyed, or programmed, by applying an excessive current, or a programming current.

The polysilicon fuse 10 includes a polysilicon pattern 12 that is formed of a second layer polysilicon film, which is different from the polysilicon film used for forming gate electrodes of transistors. The polysilicon fuse 10 further includes metal wires 14a and 14b that act as electrodes to supply electric voltage and current to the polysilicon pattern for destroying the polysilicon fuse.

The polysilicon pattern 12 is formed on an underlying insulation film (not shown in the drawing), which is formed over a surface of a semiconductor substrate (not shown in the drawing). The polysilicon pattern 12 includes electrode regions 16a and 16b, which are arranged on the left and right sides in the drawing, and a resistor region 18 between the electrode regions 16a and 16b. The resistor region 18 has a width (the dimension in the vertical direction in FIG. 1) smaller than that of the electrode regions 16a and 16b, and straightly extends between the electrode regions 16a and 16b.

In the exemplary embodiment shown in FIG. 1, the resistor region 18 has a width of 1.0 μm, and a length (the dimension along the horizontal direction in FIG. 1) of 2.5 μm, and a thickness (the dimension perpendicular to the drawing sheet of FIG. 1) of 200 nm.

In the exemplary embodiment shown in FIG. 1, the resistor region 18 is lightly doped with phosphorus and has a sheet resistance of 2.0 kΩ/sq. The electrode regions 16a and 16b are heavily doped with phosphorus and have a lower resistance.

An interlayer dielectric film (not shown in the drawing) is formed over the polysilicon pattern 12. At portions of the interlayer dielectric film over the electrode regions 16a and 16b, contact holes 20 are formed. Furthermore, metal wires 14a and 14b are formed on the interlayer dielectric film. The metal wires 14a and 14b are connected to the respective electrode regions 16a and 16b through plugs, which are formed of tungsten, filled in the respective contact holes 20.

When the dimension of the contact holes 20 is sufficiently large, it is also possible to connect the metal wires 14a and 14b to the electrode regions 16a and 16b without filling the contact holes with plugs. In either case, the metal wires 14a and 14b can be connected to the electrode regions 16a and 16b with a low contact resistance, because the electrode regions 16a and 16b are heavily doped.

According to various exemplary embodiments, in the initial state before applying the programming current, the metal wires 14a and 14b are connected by the polysilicon pattern 12. Accordingly, the polysilicon fuse 10 is in a conductive state.

In the exemplary embodiment shown in FIG. 1, the polysilicon fuse 10 has a resistance, before it is destroyed, of about 3.5 kΩ. As explained above, the electrode regions 16a and 16b are heavily doped and have a low resistance. Further, the contact resistance between the metal wires 14a and 14b and the electrode regions 16a and 16b is low. Accordingly, the resistance of the polysilicon fuse 10 is effectively the same as the resistance of the resistor region 18.

After a programming current is applied, the resistor region 18 is burned out and is disconnected. Accordingly, the polysilicon fuse 10 changes to an open, or non-conductive, state.

In the exemplary polysilicon fuse 10 shown in FIG. 1, substantially the entire portion the resistor region 18 has a constant dopant concentration and a constant sheet resistance. That is, the resistor region 18 of the polysilicon fuse 10 is formed of a polysilicon film having a high sheet resistance of 2.0 kΩ/sq.

In the polysilicon fuse disclosed in Patent Document 5, on the contrary, nearly the entire portion of the fuse body (which corresponds to the resistor region 18 shown in FIG. 1) is formed of a heavily doped polysilicon film having a low sheet resistance. That is, only the central portion of the fuse body is made to have a high resistance.

Because the resistor region 18 is formed of a polysilicon film having a high sheet resistance, the exemplary polysilicon fuse 10 shown in FIG. 1 has a higher resistance than the resistances of the conventional fuses. The higher resistance of the fuse increases the amount of heat generated with the same current. According to various exemplary embodiments, therefore, the fuse can be destroyed with a smaller current.

Furthermore, by forming the entire portion of the resistor region 18 using a high resistance polysilicon film, less electric power (current×voltage) is necessary to destroy the fuse 10.

In the exemplary polysilicon fuse 10 shown in FIG. 1, not only the central portion of the resistor region 18, which will be burned out, but also the portions on both sides of the central portion have a high electric resistance. Accordingly, the thermal resistance of the portions on both sides, which is primarily determined by the thermal conduction by free carriers, is also high. As a result, the flow of heat to the metal wires 14a and 14b through the portions on both sides of the central portion is suppressed. Accordingly, the amount of heat generation necessary to make the central portion of the resistor region 18 reach to a temperature necessary to burn out is decreased.

In practice, the dopant concentration in the end portions of the resistor region 18 may be increased by the diffusion of the dopant heavily doped in the electrode regions 16a and 16b. In such a case, only the major portion of resistor region 18 except for the end portions adjacent to the electrode regions has a high sheet resistance.

When, for example, arsenic, which has a low diffusion coefficient, is used to dope the electrode regions 16a and 16b, the polysilicon fuse 10 has a resistance of about 5 kΩ. This value is substantially the same as the value calculated from the dimension of the resistor region 18 and the sheet resistance of the polysilicon film used to form the resistor region.

On the other hand, when, for example, phosphorus, which has a high diffusion coefficient, is used to dope the electrode regions 16a and 16b, the resistance of the fuse 10 is about 3.5 kΩ. This value is smaller than the calculated value. Even in the case that the resistance of the fuse is decreased due to the diffusion of the dopant from the electrode regions 16a and 16b, the resistance of the fuse still can be made sufficiently high by appropriately setting the dimension of the resistor region and the sheet resistance of the polysilicon film. Accordingly, the exemplary fuse can be destroyed with a low current, or a low power.

According to various exemplary embodiments, the shape of the polysilicon pattern 12 is not limited to that shown in FIG. 1. Rather, the polysilicon pattern 12 may be formed in any shapes and dimensions as previously proposed.

For example, it is not necessary to form the resistor region 18 in a straight shape, but may be formed to have a bent portion. Also, it is not necessary to form the resistor region 18 to have a fixed width, but may be formed to have a notched portion, which has a narrower width than the remaining portion. When forming the electrode regions 16a and 16b wider than the resistor region 18, it is possible to provide tapered regions with varying width between them.

The resistor region 18 may preferably have a sheet resistance in a range of about 1.7 to 6 kΩ/sq. As explained above, the higher sheet resistance is preferable to decrease the current and the power necessary to destroy the fuse. However, an excessively high sheet resistance increases the variation of the sheet resistance, and decreases the programming yield of the fuse. Further, the polysilicon fuse may preferably have a resistance equal to or higher than about 3 kΩ.

The exemplary semiconductor integrated circuits including the polysilicon fuse may be formed by adding a few steps for forming the polysilicon pattern 12 to a conventional manufacturing process for forming, for example, CMOS logic semiconductor integrated circuits.

It is possible to form the fuse using the same polysilicon film used for forming gate electrodes of the transistors. However, it is generally preferable to form the fuse using a polysilicon film of a layer higher than the layer used for forming the gate electrodes.

When forming the fuse using the same polysilicon film used for forming the gate electrodes, after depositing a polysilicon film, portions of the film for forming the gate electrodes are heavily doped using a mask. On the other hand, portions of the film for forming the fuses are lightly doped with, for example, phosphorus, to have a sheet resistance of 1.7 to 6 kΩ/sq by using a separate mask.

The light doping may be performed only to the portions for forming the resistor regions of the fuses. Usually, however, the light doping is performed both to the portions for forming the resistor regions and the electrode regions. The electrode regions, which require heavy doping, are further doped with, for example, phosphorus or arsenic, by using a different mask. The heavy doping of the electrode regions may be performed simultaneously with the doping of the portions for forming gate electrodes by using a common mask. Thereafter, the polysilicon film is patterned in the shapes necessary for the gate electrodes and the fuses.

When a higher layer polysilicon film is used to form the fuses, the doping of, for example, phosphorus for adjusting the sheet resistance of the resistor region to about 1.7 to 6 kΩ/sq. may be performed to the entire polysilicon film, without using a mask. The resistance of about 1.7 to 6 kΩ/sq. is also suitable for forming resistor elements. Therefore, the doping of the portions for forming the resistor elements may be performed simultaneously with the doping to the resistor regions. Accordingly, the doping without using a mask may be performed even in the case that the same polysilicon film is also used for forming resistor elements.

Accordingly to various exemplary embodiments, when the same polysilicon film is used for forming the fuses and resistor elements, the polysilicon fuse may be formed using fewer masks than the fuse disclosed in Patent Document 5. That is, an additional mask to dope boron in the central portion of the fuse body is not required.

It is also possible to selectively dope the portions for forming the fuses using a mask to adjust the sheet resistance suitable for the resistor region of the polysilicon fuse. Such a selective doping may be necessary when, for example, the same polysilicon film is used for forming other elements. A separate mask is used for the heavy doping of, for example, phosphorus or arsenic, in the electrode regions. However, the heavy doping may be performed simultaneously with the doping to the electrode regions of resistor elements using a common mask.

After the doping steps, the polysilicon film is patterned in the shapes necessary for the fuses, resistor elements, and the other elements.

In either case, the light and the heavy doping may be performed using a known ion implantation technique. The order of the doping and patterning steps is not fixed. That is, the light doping to the resistor regions or to the both of the resistor regions and the electrode regions, the heavy doping to the electrode region, and the patterning may be performed in an arbitrary order.

In other words, the polysilicon pattern 12 including the lightly doped resistor region 18 and the heavily doped electrode regions 16a and 16b may be formed by performing each of the light doping at least on the resistor region and the heavy doping selectively (i.e., without doping to the resistor region) on the electrode regions before or after the patterning.

In the exemplary method described above, phosphorus or arsenic, which is an n-type dopant, is used to dope the resistor region 18 and the electrode regions 16a and 16b. However, it is also possible to use a p-type dopant such as boron to dope the resistor region 18 and the electrode regions 16a and 16b. In either case, the resistor region 18 and the electrode regions 16a and 16b are doped to have the same conduction type.

After the doping and the patterning of the polysilicon film, an interlayer dielectric film is formed to cover the entire polysilicon patterns 12 and contact holes 20 for connecting the electrode regions 16a and 16b to the metal wires 14a and 14b are formed in the interlayer dielectric film.

Next, an exemplary memory circuit will be explained as an exemplary application of the polysilicon fuse.

FIG. 2 shows an exemplary one-bit memory circuit including a polysilicon fuse. The memory circuit 30 shown in FIG. 2 is included in a semiconductor integrated circuit according to this invention. The memory circuit 30 includes a polysilicon fuse 32, a writing circuit 34 that programs the polysilicon fuse 32, and an inverter 36.

The polysilicon fuse 32 has the construction shown in FIG. 1. The polysilicon fuse 32 is connected between the input terminal of the inverter 36 and the ground GND.

The writing circuit 34 supplies the destruction voltage and current for writing, or programming, the polysilicon fuse 32. The writing circuit 34 includes a P-type MOS transistor (PMOS) 38 and a resistor element 40. The source of the PMOS 38 is connected to a high voltage power-supply Vdd1, and the drain of the PMOS 38 is connected to the input terminal of the inverter 36. Further, a select signal A is input to the gate of the PMOS 38. The resistor element 40 is connected between the Vdd1 and the gate of the PMOS 38.

The inverter 36 includes a PMOS 42, N-type MOS transistor (NMOS) 44, and a resistor element 46. Sources of the PMOS 42 and the NMOS 44 are connected to a low voltage power-supply VDD and the ground GND, respectively. Drains of the PMOS 42 and the NMOS 44 are connected to the output terminal OUT. Gates of the PMOS 42 and the NMOS 44 are coupled to form the input terminal of the inverter 36. The resistor element 46 is connected between the power-supply VDD and the input terminal of the inverter 36.

In the memory circuit 30, the resistance of the resistor element 46 is far larger than the resistance of the polysilicon fuse 32 before it is destroyed, i.e., the resistance of the polysilicon fuse in the initial (conductive) state. Accordingly, before the polysilicon fuse 32 is destroyed, the potential of the input terminal of the inverter 36, which is determined by voltage division between the resistor element 46 and the polysilicon fuse 32, is in LOW level. Accordingly, the output terminal OUT is in HIGH level, which is the voltage level supplied from VDD.

In order to destroy and program the polysilicon fuse, the select signal A is set to the LOW level, and the PMOS 38 turns-on. Accordingly, an electric power with the voltage and current sufficient for destruction is supplied from the high voltage power-supply Vdd1 to the polysilicon fuse 32. Thereby, the polysilicon fuse 32 is destroyed and changes to the open state. As a result, the potential of the input terminal of the inverter 36 changes to the HIGH level, and the output terminal OUT changes to the LOW level.

The high voltage power-supply Vdd1 is, for example, a pad electrode to which an electric power to destroy the fuse 32 is supplied. When a plurality of memory circuits 30 is included in a semiconductor integrated circuit, the high voltage power-supply Vdd1 is used commonly by the plurality of memory circuits 30. On the other hand, VDD is the power-supply of, for example, 3.3 V, for operating the inverter 36 and other circuitries integrated in the semiconductor integrated circuit.

Each of the plurality of memory circuits is selected by the select signal A, which may be generated within the semiconductor integrated circuit. In the exemplary memory circuit 30, the circuits that receive LOW level select signals A are selected. The electric power with the voltage and current for destruction is supplied from the power-supply Vdd1 to the polysilicon fuse 32 through the PMOS 38 in each of the selected memory circuits 30.

As explained above, an exemplary one bit memory circuit 30 is constructed using the polysilicon fuse 32. The output of the memory circuit 30 may be used for various purposes. For example, various circuit parameters of circuitries integrated in the semiconductor integrated circuit may be adjusted by the output signals of one or more memory circuits 30.

Next, an exemplary liquid crystal display will be explained as another exemplary application of the polysilicon fuse.

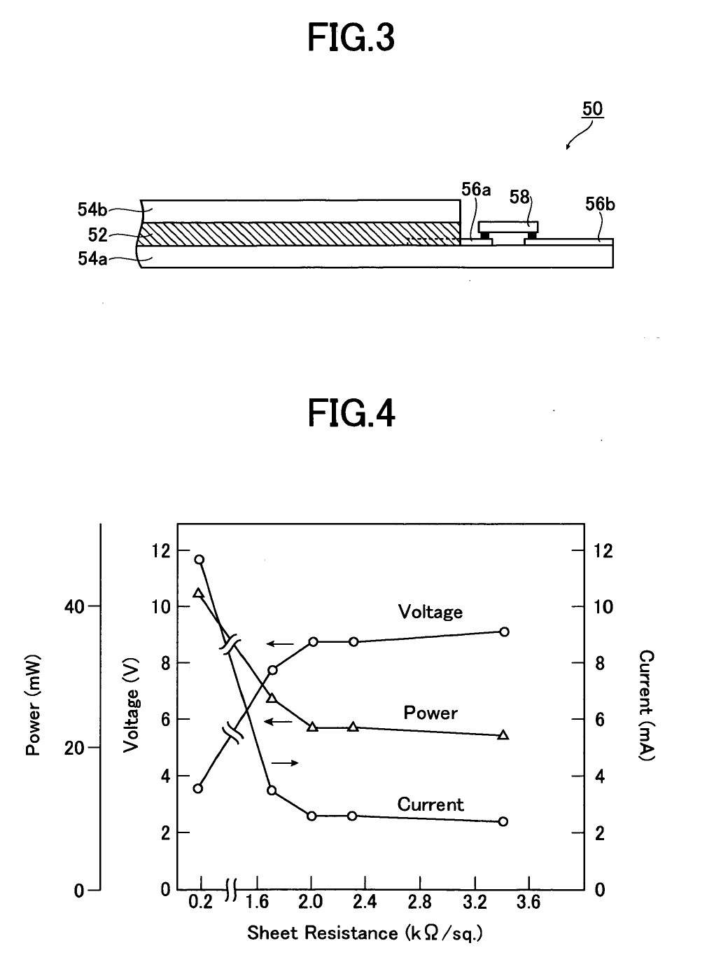

FIG. 3 is an exemplary drawing showing a semiconductor integrated circuit 58 according to this invention, which includes polysilicon fuses, mounted on a liquid crystal display panel 50.

The liquid crystal display panel 50 shown in FIG. 3 is arranged with a liquid crystal 52 injected between two glass plates 54a and 54b. Thin-film transistors (TFTs) (not shown in the drawing) and wires 56a and 56b are formed on the surface of one of the glass plates 54a, which is the lower glass plate on the drawing. The TFT controls the polarity of liquid crystal in each picture element so that a picture is displayed.

The wires 56a and 56b are formed of indium-tin oxide (ITO) film. The ITO film is a translucent film, and is generally used as a transparent electrode film in liquid crystal and other display devices. Films of other materials such as indium-zinc oxide (IZO) and indium-tin-zinc oxides (ITZO) may also be used as transparent electrode films.

The semiconductor integrated circuit 58 is a driver IC that controls the liquid crystal display 50. The driver IC 58 is mounted on the surface of the lower glass plate 54a facedown, and is connected to the wires 56a and 56b. That is, the lower glass plate 54a of the liquid crystal display panel 50 is also used as a substrate to mount the driver IC 58.

The wires 56a on the left on the drawing transmit signals from the driver IC 58 to the TFTs formed on the surface of the lower glass plate 54a. The wires 56b on the right on the drawing transmit signals and supply power-supply potentials to the driver IC 58 from the outside of the display 50.

The driver IC 58 includes polysilicon fuses having the structure shown in FIG. 1. The polysilicon fuses are used to adjust various circuit parameters such as resistance values and capacitance values in the driver IC 58. Each of the fuses can be programmed and changed from the conductive to the non-conductive state by supplying an electric power with voltage and current sufficient to destroy the fuse through the wire 56b at the right on the drawing.

Here, the wires 56a and 56b formed of an ITO film have a high resistance. Accordingly, if the conventional polysilicon fuse that requires a high programming current is used, it is difficult to destroy the fuse by supplying an electric power from outside of the driver IC 58 through the wire 56b due to a large voltage drop in the wire 56b.

According to various exemplary embodiments, on the other hand, the resistance of the fuse is high and the fuse can be destroyed with a small current. Accordingly, the fuse can be destroyed easily and surely even if the resistance of the wire 56b, which is formed of ITO, is high.

### Embodiment 1

Using a polysilicon film with a sheet resistance of 2.0 kΩ/sq., polysilicon fuses having the structure shown in FIG. 1 were formed. Voltages and currents required to program ten of these fuses were measured. The resistance of the fuses before the destruction was about 3.5 kΩ. The average voltage and current required for programming the fuses were about 8.8 V and 2.6 mA, respectively. All of the ten fuses can be programmed, i.e., can be destroyed and turned into the non-conductive states.

As a result, the polysilicon fuse shown in FIG. 1 can be programmed with a sufficiently low programming current.

The measured programming current is well within the range that can be supplied from outside of the semiconductor integrated circuit through the wire formed of a transparent electrode film.

On the other hand, the measured programming voltage is higher than the power-supply voltage of generally used logic semiconductor integrated circuit (for example, 3.3V). The measured voltage is also higher than the breakdown voltage of the transistor generally used in the logic semiconductor integrated circuit. Accordingly, in order to integrate in the semiconductor integrated circuits that operate with low power-supply voltages, fuses with lower programming voltages are desired.

Thus, it should be mentioned that the polysilicon fuse according to this exemplary embodiment is not necessarily suitable to integrate in any types of semiconductor integrated circuits. In the case of the driver IC 58, however, in addition to a low power-supply voltage of, for example, 3.3 V, a high power-supply voltage of, for example, 18 V is supplied in order to output high voltage output signals to drive the liquid crystal. The high power-supply voltage can be used to program the fuses. Moreover, the writing circuit 34 shown in FIG. 2 can be constructed using a high breakdown voltage transistor used for driving the liquid crystal.

Accordingly, the exemplary polysilicon fuse that requires a low destruction current and a relatively high destruction voltage is particularly suitable for integrating in semiconductor integrated circuits to which a power-supply voltage of equal to or higher than, for example, 10 V is supplied.

Note that, however, the programming voltage may be decreased by, for example, adjusting the dimension of the polysilicon pattern 12, even though a polysilicon film of the same sheet resistance (2.0 kΩ/sq.) is used. For example, by decreasing the length of the polysilicon pattern 12 to 2.0 μm, the programming voltage is decreased to about 7.0 V. In this case, the resistance of the fuse is about 2.8 kΩ. The programming current is slightly increased to about 3.5 mA.

No adverse effects on the interlayer dielectric film covering the resistor region 18, or on the higher layer interlayer dielectric films were observed after the programming of the fuse. Accordingly, it is not necessary to add a step to remove the interlayer dielectric films over the resistor region 18.

### Embodiment 2

Next, fuses having the structure shown in FIG. 1 were formed using polysilicon films having various sheet resistances, and the programming voltages and currents of these fuses, i.e., the voltages and currents required for destroying the polysilicon fuses, were measured. FIG. 4 is a graph showing the results of the measurement. The results of the measurement are also summarized in Table 1.

TABLE 1

| Sheet | Fuse | Programming | Programming | Programming |
|---|---|---|---|---|
| resistance | resistance | voltage | current | Power |
| (Ω/sq.) | (Ω) | (V) | (mA) | (mW) |
| 160 | 245 | 3.6 | 11.7 | 42 |
| 1.7 k | 2.9 k | 7.8 | 3.5 | 27 |
| 2.0 k | 3.5 k | 8.8 | 2.6 | 23 |
| 2.3 k | 4.0 k | 8.8 | 2.6 | 23 |
| 3.4 k | 6.0 k | 9.2 | 2.4 | 22 |

The graph of FIG. 4 and Table 1 shows that the fuse resistance increases as the polysilicon film sheet resistance increases. For example, when the polysilicon film sheet resistance is equal to or higher than 1.7 kΩ/sq., the fuse resistance is equal to or higher than about 3 kΩ. The increase in the polysilicon film sheet resistance also increases the programming voltage and decreases the programming current.

For example, when the polysilicon film sheet resistance is 1.7 kΩ/sq., the programming current is about 3.5 mA, which is less than about ⅓ of the value (11.7 mA) for the sheet resistance of 160 Ω/sq. The programming current further decreases to about 2.6 mA when the sheet resistance increases to 2.0 kΩ/sq,, which is less than about ¼ of the value for the sheet resistance of 160 Ω/sq.

Furthermore, the power required for the programming also decreases as the polysilicon film sheet resistance increases. For example, when the polysilicon film sheet resistance is 1.7 kΩ/sq. and 2.0 kΩ/sq., the programming powers are about 27 mW and about 23 mW, respectively. These values are about 64% and 55% of the value (42 mW) for the sheet resistance of 160 Ω/sq. The decrease of the power necessary for programming decreases the damage to the interlayer dielectric film and the passivation film, as previously noted.

The graph of FIG. 4 and Table 1 also indicate that the programming current and the power do not markedly decrease when the polysilicon film sheet resistance increases beyond 2.0 kΩ/sq. Decreasing the amount of doping may further increase the polysilicon film sheet resistance. When the sheet resistance is increased beyond, for example, 6 kΩ/sq., however, the controllability of the sheet resistance degrades, and the variation in the sheet resistance increases. Accordingly, in practice, it is preferable to set the sheet resistance of the polysilicon film between about 1.7 to 6 kΩ/sq.

Changing of the thickness of the polysilicon film also changes the sheet resistance of the film. Usually, the thickness of the polysilicon film may be set within a range of about 100 to 400 nm. In order to increase the sheet resistance and to decrease the programming current of the fuse, relatively thin thickness of about 250 nm or less is preferable.

As explained above, according to various exemplary semiconductor integrated circuits and according to various exemplary methods of forming semiconductor integrated circuits, increasing the sheet resistance of the polysilicon film for forming the fuse lowers the current required to program the polysilicon fuse. Accordingly, an area required for arranging the circuit to supply the programming current can be decreased, and the area of the semiconductor integrated circuit can be decreased.

Moreover, the circuit parameter of the semiconductor integrated circuit can be adjusted by programming the fuse even if the programming current is supplied from outside of the semiconductor integrated circuit through a wire having a high resistance.

Thus far, exemplary semiconductor integrated circuits according to this invention were explained in detail in reference to specific embodiments. Needless to say, this invention is not limited to the specific embodiments, and permits various improvements and modifications within the spirit of the invention.

As explained above, the exemplary polysilicon fuse according to this invention is particularly suitable to integrate in a driver IC that drives a liquid crystal display. However, the exemplary polysilicon fuse may be integrated in various semiconductor integrated circuits that require adjustment of circuit parameters such as resistance and capacitor values, as long as the relatively high programming current is acceptable.

1. A semiconductor integrated circuit comprising:
a fuse, which is programmable by supplying a programming current, comprising a polysilicon pattern formed of a polysilicon film, the polysilicon pattern including electrode regions and a resistor region between the electrode regions,
wherein at least a portion of the resistor region, except for end portions adjacent to the electrode regions, has a sheet resistance of 1.7 to 6 kΩ/sq.

2. The semiconductor integrated circuit of claim 1, wherein a resistance of the fuse is not lower than about 3 kΩ.

3. The semiconductor integrated circuit of claim 1, wherein each of the end portions of the resistor region has a first width and is connected directly, or through a tapered region, to the electrode region having a second width larger than the first width.

4. The semiconductor integrated circuit of claim 1, further comprising a resistor element formed of the polysilicon film having the sheet resistance of 1.7 to 6 kΩ/sq.

5. A semiconductor integrated circuit mounted on a substrate having a transparent electrode film, the semiconductor integrated circuit comprising:
a fuse comprising a polysilicon pattern formed of a polysilicon film, the polysilicon pattern including electrode regions and a resistor region between the electrode regions, the fuse being programmable by supplying a programming current from outside of the semiconductor integrated circuit through an external wire formed by the transparent electrode film,
wherein at least a portion of the resistor region, except for end portions adjacent to the electrode regions, has a sheet resistance of 1.7 to 6 kΩ/sq.

6. The semiconductor integrated circuit of claim 5, wherein a resistance of the fuse is not lower than about 3 kΩ.

7. The semiconductor integrated circuit of claim 5, wherein each of the end portions of the resistor region has a first width and is connected directly, or through a tapered region, to the electrode region having a second width larger than the first width.

8. The semiconductor integrated circuit according to claim 5, wherein the transparent film is one of an indium-tin oxide, an indium-zinc oxide, and an indium-tin-zinc oxide film.

9. A method of forming a semiconductor integrated circuit comprising a polysilicon fuse including a polysilicon pattern, the method comprising:
forming a polysilicon film over a surface of a semiconductor substrate;
patterning the polysilicon film to form the polysilicon pattern to include electrode regions and a resistor region between the electrode regions;
doping, before or after the patterning, at least the resistor region to have a sheet resistance of 1.7 to 6 kΩ/sq.; and
doping, before or after the patterning, the electrode regions more heavily than the resistor region without doping the resistor region.

10. The method of claim 9, wherein the patterning and the doping are performed such that the fuse has a resistance not lower than about 3 kΩ.

11. The method of claim 9, wherein the patterning is performed such that each of end portions of the resistor region has a first width and is connected directly, or through a tapered region, to the electrode region having a second width larger than the first width.

12. The method of claim 9, wherein:
the semiconductor integrated circuit further comprises a resistor element; and
the doping of the resistor region is performed simultaneously to doping a portion of the polysilicon film for forming the resistor element.

13. A method of adjusting a circuit parameter of a semiconductor integrated circuit, comprising:
integrating a fuse comprising a polysilicon pattern formed of a polysilicon film in the semiconductor integrated circuit, the polysilicon pattern including electrode regions and a resistor region between the electrode regions;
mounting the semiconductor integrated circuit on a substrate having an external wire formed of a transparent electrode film; and
programming the fuse by supplying a programming current to the fuse through the external wire,
wherein at least a portion of the resistor region, except for end portions adjacent to the electrode regions, has a sheet resistance of 1.7 to 6 kΩ/sq.

14. The method of claim 13, wherein a resistance of the fuse is not lower than about 3 kΩ.

15. The method of claim 13, wherein each of the end portions of the resistor region has a first width and is connected directly, or through a tapered region, to the electrode region having a second width larger than the first width.

16. The method of claim 13, wherein the transparent film is one of an indium-tin oxide, an indium-zinc oxide, and an indium-tin-zinc oxide film.
